(19) United States
(12) Patent Application Publication
(10) Pub. No.: US 2013/0157044 A1
(43) Pub. Date: Jun. 20, 2013

(54) COATED ARTICLE AND METHOD FOR MAKING SAME

(71) Applicant: DA-HUA CAO, Shenzhen City (CN)

(72) Inventor: DA-HUA CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/481,011

(22) Filed: May 25, 2012

(30) Foreign Application Priority Data
Dec. 15, 2011 (CN) 201110420332.1

(51) Int. Cl. B32B 9/04; B32B 33/00; C23C 14/46; C23C 14/14; B32B 15/04; C23C 14/35

(52) U.S. Cl. 428/336; 428/457; 204/192.15; 204/192.11

(57) ABSTRACT

A coated article includes a substrate, a base layer directly formed on the substrate, an intermediate layer directly formed on the base layer, and a hydrophobic layer directly formed on the intermediate layer. The base layer is a chromium layer. The intermediate layer is a chromium carbide layer. The hydrophobic layer is a fluorine-carbon-hydrogen layer. The coated article has a good hydrophobic property and a good corrosion resistance.

### BACKGROUND

1. Technical Field

The present disclosure relates to coated articles and a method for making the coated articles.

2. Description of Related Art

Hydrophobic surfaces have a water contact angle greater than 90° and are known to be excellent in repelling water. However, layers made by the physical vapor deposition (PVD) technology usually have poor hydrophobic properties. So impurities such as grease, dirt or fingerprints stick easily onto the surface of the PVD layers.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary coated article;

FIG. 2 is a schematic view of a vacuum sputtering device for fabricating the coated article in FIG. 1.

### DETAILED DESCRIPTION

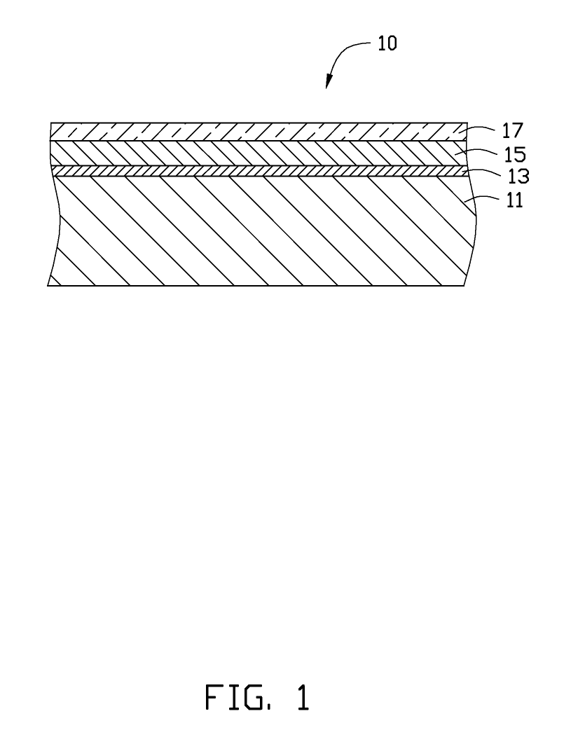

FIG. 1 shows a coated article 10 according to an exemplary embodiment. The coated article 10 includes a substrate 11, a base layer 13 directly formed on the substrate 11, an intermediate layer 15 directly formed on the base layer 13, and a hydrophobic layer 17 formed on the intermediate layer 15. As used in this disclosure, “directly” means a surface of one layer is in contact with a surface of the other layer.

The substrate 11 is made of stainless steel.

The base layer 13 is a chromium layer having a thickness of about 0.05 μm to about 0.2 μm.

The intermediate layer 15 is a chromium carbide layer having a thickness of about 1.5 μm to about 2.0 μm.

The hydrophobic layer 17 is a fluorine-carbon-hydrogen layer having a thickness of about 0.2 μm to about 0.5 μm. The hydrophobic layer 17 has a surface facing (i.e., in contact with) the atmosphere. The hydrophobic layer 17 has a good hydrophobicity having a water contact angle of about 108° to about 120°, which means the coated article 10 has a good stain resistance. In addition, the hydrophobic layer 17 is transparent, so the coated article 10 presents a silver-white color of the intermediate layer 15. Furthermore, the hydrophobic layer 17 also has a good abrasion resistance and a good corrosion resistance.

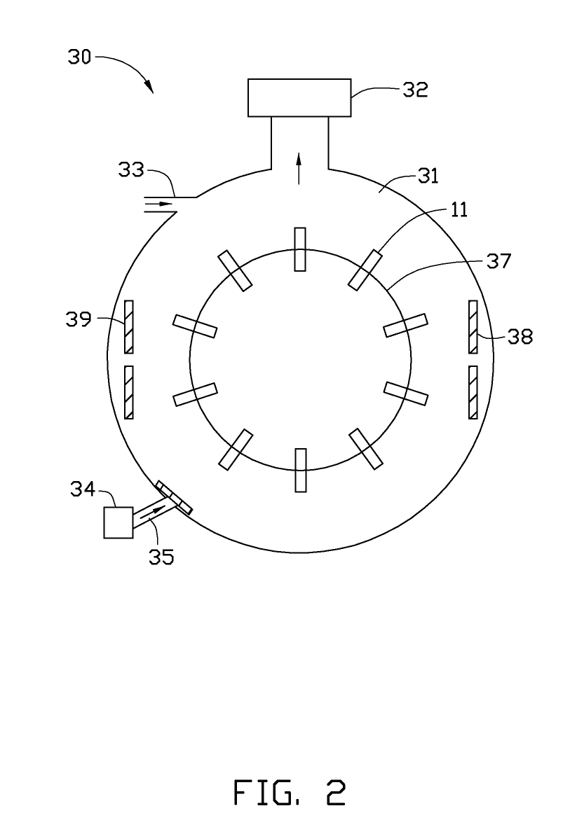

FIG. 2 shows a vacuum sputtering device 30, which includes a vacuum chamber 31, and a vacuum pump 32 connected to the vacuum chamber 31, a gas channel 33, an ion source chamber 34, and an ion source channel 35 connected to the vacuum chamber 31 and the ion source chamber 34. The vacuum pump 32 is used for evacuating the air from the vacuum chamber 31. The vacuum chamber 31 has a rotary rack 37, at least one chromium target 38, and at least two polytetrafluoroethylene (PTFE) targets 39 positioned therein. The rotary rack 37 holding the substrate 11 revolves along a circular path; the substrate 11 is also revolved about its own axis while being carried by the rotary rack 37. The sputtering gas and the reaction gas can be fed into the vacuum chamber 31 through the gas channel 33. Ion beams produced in the ion source chamber 34 can be fed into the vacuum chamber 31 through the ion source channel 35.

A method for making the coated article 10 may include the following steps:

The substrate 11 made of stainless steel is provided and pretreated. The pre-treating process may include polishing and washing the substrate 11 in order to remove impurities such as grease or dirt from the substrate 11.

The base layer 13 is magnetron sputtered on the substrate 11. Magnetron sputtering of the base layer 13 is implemented in the vacuum chamber 31. The vacuum chamber 21 is heated to a temperature of about 110° C. to about 180° C. Argon gas (abbreviated as Ar) is used as sputtering gas and is fed into the vacuum chamber 21 at a flow rate of about 180 standard-state cubic centimeters per minute (sccm) to about 250 sccm. The at least one chromium target 38 is supplied with electrical power of about 13 kw to about 18 kw. A negative bias voltage of about −150 V is applied to the substrate 11. The depositing of the base layer 13 takes about 8 min to about 15 min.

The intermediate layer 15 is magnetron sputtered on the base layer 13. Magnetron sputtering of the intermediate layer 15 is implemented in the vacuum chamber 31. Acetylene is used as reaction gas and is fed into the vacuum chamber 21 at a flow rate of about 60 sccm to about 90 sccm. The at least one chromium target 38 is supplied with electrical power of about 14 kw to about 19 kw. A negative bias voltage of about −100 V is applied to the substrate 11. The flow rate of Ar and the temperature of vacuum chamber 31 are the same with vacuum sputtering of the base layer 13. The depositing of the intermediate layer 15 takes about 80 min to about 120 min.

The hydrophobic layer 17 is ion beam sputtered on the intermediate layer 15. Ion beam sputtering of the hydrophobic layer 17 is implemented in the vacuum chamber 31. Ar is fed into the ion source chamber 34 and ionized to Ar ions. The Ar ions are fed into the vacuum chamber 31 through the ion source channel 35 and sputter the PTFE targets. The atoms of the PTFE targets deviate from the PTFE targets and deposit on the intermediate layer 15. The sputtering energy of the argon ion is about 1.0 keV to about 1.5 keV, the ion current is about 30 mA to about 40 mA, the low energy ion beam energy is about 100 eV to about 300 eV, the intermediate ion beam energy is about 500 eV to about 750 eV. A negative bias voltage of about −50 V is applied to the substrate 11.

### EXAMPLES

Experimental examples of the present disclosure are described as followings.

### Example 1

The vacuum sputtering device 30 in example 1 was a medium frequency magnetron sputtering device.

The substrate 11 was made of stainless steel 304.

Sputterring to form the base layer 13, wherein the vacuum chamber 21 was heated to a temperature of about 130° C. Ar was fed into the vacuum chamber 21 at a flow rate of about 220 sccm. The chromium targets 38 were supplied with a power of about 15 kw, and a negative bias voltage of about −150 V was applied to the substrate 11. The depositing of the base layer 13 took about 10 min. The base layer 13 had a thickness of about 0.1 μm.

Sputterring to form the intermediate layer 15, wherein acetylene was fed into the vacuum chamber 31 at a flow rate of about 60 sccm. The chromium targets 38 were supplied with a power of about 16 kw, and a negative bias voltage of about −100 V was applied to the substrate 11. The flow rate of the Ar and the temperature of vacuum chamber 31 were substantially the same with vacuum sputtering of the base layer 13. The depositing of the intermediate layer 15 took about 80 min. The intermediate layer 15 had a thickness of about 1.6 μm.

Sputterring to form the hydrophobic layer 17, wherein the sputtering energy of the argon ion was about 1.5 keV, the ion current was about 30 mA to about 40 mA, the low energy ion beam energy was about 100 eV to about 300 eV, the intermediate ion beam energy was about 500 eV to about 750 eV. A negative bias voltage of about −50 V was applied to the substrate 11. The hydrophobic layer 17 had a thickness of about 0.3 μm.

The coated article 10 had a water contact angle of about 115°.

### Example 2

The vacuum sputtering device 30 and the substrate 11 in example 2 were the same in example 1.

Sputterring to form the base layer 13, wherein the vacuum chamber 21 was heated to a temperature of about 140° C. Ar was fed into the vacuum chamber 21 at a flow rate of about 200 sccm. The chromium targets 38 were supplied with a power of about 16 kw, and a negative bias voltage of about −150 V was applied to the substrate 11. The depositing of the base layer 13 took about 15 min. The base layer 13 had a thickness of about 0.15 μm.

Sputterring to form the intermediate layer 15, wherein acetylene was fed into the vacuum chamber 31 at a flow rate of about 80 sccm. The chromium targets 38 were supplied with a power of about 17 kw, and a negative bias voltage of about −100 V was applied to the substrate 11. The flow rate of the Ar and the temperature of vacuum chamber 31 are substantially the same with vacuum sputtering of the base layer 13. The depositing of the intermediate layer 15 took about 90 min. The intermediate layer 15 had a thickness of about 1.8 μm.

Sputterring to form the hydrophobic layer 17, wherein the sputtering energy of the argon ion was about 1.4 keV, the ion current was about 34 mA to about 38 mA, the low energy ion beam energy was about 100 eV to about 300 eV, the intermediate ion beam energy was about 500 eV to about 750 eV. A negative bias voltage of about −50 V was applied to the substrate 11. The hydrophobic layer 17 had a thickness of about 0.4 μm.

The coated article 10 had a water contact angle of about 118°.

### Example 3

The vacuum sputtering device 30 and the substrate 11 in example 3 were the same in example 1.

Sputterring to form the base layer 13, wherein the vacuum chamber 21 was heated to a temperature of about 150° C. Ar was fed into the vacuum chamber 21 at a flow rate of about 220 sccm. The chromium targets 38 were supplied with a power of about 17 kw, and a negative bias voltage of about −150 V was applied to the substrate 11. The depositing of the base layer 13 took about 8 min. The base layer 13 had a thickness of about 0.1 μm.

Sputterring to form the intermediate layer 15, wherein acetylene was fed into the vacuum chamber 31 at a flow rate of about 90 sccm. The chromium targets 38 were supplied with a power of about 18 kw, and a negative bias voltage of about −100 V was applied to the substrate 11. The flow rate of the Ar and the temperature of vacuum chamber 31 were substantially the same with vacuum sputtering of the base layer 13. The depositing of the intermediate layer 15 took about 100 min. The intermediate layer 15 had a thickness of about 2.0 μm.

Sputterring to form the hydrophobic layer 17, wherein the sputtering energy of the argon ion was about 1.5 keV, the ion current was about 38 mA to about 40 mA, the low energy ion beam energy was about 100 eV to about 300 eV, the intermediate ion beam energy was about 500 eV to about 750 eV. A negative bias voltage of about −50 V is applied to the substrate 11. The hydrophobic layer 17 had a thickness of about 0.5 μm.

The coated article 10 had a water contact angle of about 120°.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a base layer directly formed on the substrate, the base layer being a chromium layer;
an intermediate layer directly formed on the base layer, the intermediate layer being a chromium carbide layer; and
a hydrophobic layer directly formed on the intermediate layer, the hydrophobic layer being a fluorine-carbon-hydrogen layer having a surface facing the atmosphere.

2. The coated article as claimed in claim 1, wherein the base layer has a thickness of about 0.05 μm to about 0.2 μm.

3. The coated article as claimed in claim 1, wherein the intermediate layer has a thickness of about 1.5 μm to about 2.0 μm.

4. The coated article as claimed in claim 1, wherein the hydrophobic layer has a thickness of about 0.2 μm to about 0.5 μm.

5. The coated article as claimed in claim 1, wherein the substrate is made of stainless steel.

6. The coated article as claimed in claim 1, wherein the hydrophobic layer has a water contact angle of about 108° to about 120°.

7. The coated article as claimed in claim 1, wherein the hydrophobic layer is transparent.

8. A method for making a coated article, comprising:
providing a substrate;
directly forming a base layer on the substrate, the base layer being a chromium layer;
directly forming an intermediate layer on the base layer, the intermediate layer being a chromium carbide layer; and
directly forming a hydrophobic layer on the intermediate layer, the hydrophobic layer being a fluorine-carbon-hydrogen layer having a surface facing the atmosphere.

9. The method as claimed in claim 8, wherein forming the base layer uses magnetron sputtering method, uses argon gas as sputtering gas and argon gas has a flow rate of about 180 sccm to about 250 sccm; magnetron sputtering the base layer is at a temperature of about 110° C. to about 180° C.; uses chromium targets and the chromium targets are supplied with a power of about 13 kw to about 18 kw; a negative bias voltage of about −150 V is applied to the substrate.

10. The method as claimed in claim 9, wherein magnetron sputtering the base layer takes about 8 min to about 15 min.

11. The method as claimed in claim 8, wherein forming the intermediate layer uses magnetron sputtering method, uses acetylene as reaction gas and acetylene has a flow rate of about 60 sccm to about 90 sccm; argon gas as sputtering gas and argon gas has a flow rate of about 180 sccm to about 250 sccm; magnetron sputtering the intermediate layer is at a temperature of about 110° C. to about 180° C.; uses chromium targets and the chromium targets are supplied with a power of about 14 kw to about 19 kw; a negative bias voltage of about −100 V is applied to the substrate.

12. The method as claimed in claim 11, wherein vacuum sputtering the intermediate layer takes about 80 min to about 120 min.

13. The method as claimed in claim 8, wherein forming the hydrophobic layer uses ion beam sputtering method, uses polytetrafluoroethylene targets; uses argon ions sputtering the polytetrafluoroethylene targets, the sputtering energy of the argon ions is about 1.0 keV to about 1.5 keV, the ion current is about 30 mA to about 40 mA, the low energy ion beam energy is about 100 eV to about 300 eV, the intermediate ion beam energy is about 500 eV to about 750 eV; a negative bias voltage of about −50 V is applied to the substrate.
